(19) United States
(12) Patent Application Publication
(10) Pub. No.: US 2025/0149090 A1
(43) Pub. Date: May 8, 2025

(54) SEMICONDUCTOR DEVICE

(71) Applicant: SK hynix Inc, Gyeonggi-do (KR)

(72) Inventor: Eun Seok CHOI, Gyeonggi-do (KR)

(21) Appl. No.: 18/416,890

(22) Filed: Jan. 19, 2024

(30) Foreign Application Priority Data
Nov. 6, 2023 (KR) 10-2023-0151590

(51) Int. Cl. G11C 16/04; G11C 16/10; G11C 16/16; G11C 16/26; H01L 23/00; H01L 25/065; H01L 25/18; H10B 80/00

(52) U.S. Cl. CPC G11C 16/0483; G11C 16/10; G11C 16/16; G11C 16/26; H01L 24/08; H01L 25/0657; H01L 25/18; H10B 80/00; H01L 2224/08145; H01L 2924/1431; H01L 2924/14511

(57) ABSTRACT

A semiconductor device may include a first source pass transistor controlling a connection between a global source line and a first local source line, a second source pass transistor controlling a connection between the global source line and a second local source line, a first memory block operating using a first source voltage supplied through the first local source line, and a second memory block operating using a second source voltage supplied through the second local source line.

### CROSS-REFERENCE TO RELATED APPLICATION

This application claims priority under 35 U.S.C. § 119 to Korean Patent Application No. 10-2023-0151590 filed on Nov. 6, 2023, which is incorporated herein by reference in its entirety.

### BACKGROUND

### 1. Technical Field

The present invention disclosure relates generally to an electronic device, and more particularly, to a semiconductor device.

### 2. Related Art

The integration degree (also known as integration density) of a semiconductor device is mainly determined by the area occupied by a unit memory cell. Recently, further improvements in the integration degree of semiconductor devices employing memory cells formed in a single layer over a substrate have reached a limit that is very difficult to surpass, three-dimensional semiconductor devices with memory cells stacked in many layers over a substrate have been proposed.

However, further improvements in both the structure, operational methods, and operational reliability of the three-dimensional semiconductor devises are needed and are being investigated.

### SUMMARY

According to an embodiment of the present invention disclosure, a semiconductor device is provided which includes a first source pass transistor controlling a connection between a global source line and a first local source line, a second source pass transistor controlling a connection between the global source line and a second local source line, a first memory block using a first source voltage supplied through the first local source line, and a second memory block using a second source voltage supplied through the second local source line.

According to an embodiment of the present invention disclosure, a semiconductor device may include a first source pass transistor controlling a connection between a first global source line and a first local source line, a second source pass transistor controlling a connection between a second global source line and a second local source line, and a memory block including a first sub-memory block using a first source voltage supplied through the first local source line and a second sub-memory block using a second source voltage supplied through the second local source line.

According to an embodiment of the present invention disclosure, a semiconductor device may include a peripheral circuit, a gate structure including stacked gate lines, a bonding structure positioned between the peripheral circuit and the gate structure and electrically connecting the peripheral circuit and the gate structure, local source lines positioned on the gate structure, and source pass transistors controlling a connection between the local source lines and at least one global source line.

According to an embodiment of the present invention disclosure, a semiconductor device may include a global source line; first and second local source lines electrically connected to the global source line; first and second pass transistors controlling the electrical connection between the global source line and each of the first and second local source lines respectively; a first memory block; a second memory block; and a voltage generation circuit electrically connected to the global source line, the voltage generation circuit configured to generate first and second source voltages and supplying the first and second source voltages to the global source line, wherein the first memory block operates using the first source voltage supplied through the first local source line; and wherein the second memory block operates using the second source voltage supplied through the second local source line.

These and other features and advantages of the present invention will become better understood from the following drawings and detailed description.

### BRIEF DESCRIPTION OF THE DRAWINGS

FIG. 1 is a simplified block diagram illustrating a configuration of a semiconductor device according to an embodiment of the present invention disclosure.

FIG. 2 is a simplified block diagram illustrating a configuration of a semiconductor device according to an embodiment of the present invention disclosure.

FIGS. 3A and 3B are diagrams illustrating a semiconductor device structure according to an embodiment of the present invention disclosure.

FIGS. 4A and 4B are circuit diagrams of a memory cell array of a semiconductor device according to an embodiment of the present invention disclosure.

FIGS. 5A and 5B are diagrams illustrating a configuration of a semiconductor device according to an embodiment of the present invention disclosure.

FIGS. 6A to 6D are diagrams illustrating a semiconductor device structure according to an embodiment of the present invention disclosure.

FIG. 7 is a configuration diagram of a semiconductor device according to an embodiment of the present invention disclosure.

FIG. 8 is a configuration diagram of a semiconductor device according to an embodiment of the present invention disclosure.

### DETAILED DESCRIPTION

An embodiment of the present invention disclosure provides a semiconductor device and a method of manufacturing the semiconductor device having a stable structure and improved characteristic.

An integration degree of a semiconductor device may be improved by stacking memory cells in a three dimension. In addition, a semiconductor device with a stable structure and improved reliability may be provided.

Herein after, embodiments according to the technical spirit of the present invention disclosure are described with reference to the accompanying drawings.

These and other features and advantages of the present invention will become apparent to those skilled in the art of the invention from the following detailed description in conjunction with the following drawings.

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention.

As used herein, singular forms are intended to include the plural forms as well, unless the context clearly indicates otherwise.

The term “a” or “an” element refer to one or more of the element. As such, the terms “a”, “an,” “one or more” and “at least one” can be used interchangeably.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure.

It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

Hereinbelow, in the accompanying drawings, a direction perpendicular to the top surface of a substrate is defined as a first direction FD, and two directions parallel to the top surface of the substrate and intersecting with each other are defined as a second direction SD and a third direction TD, respectively. The substrate may correspond to a single layer or a multi-layer substrate. The second direction SD may correspond to the extending direction of word lines, and the third direction TD may correspond to the extending direction of bit lines. The second direction SD and the third direction TD may intersect substantially perpendicularly with each other. In the drawings, a direction indicated by an arrow and a direction opposite thereto represent the same direction.

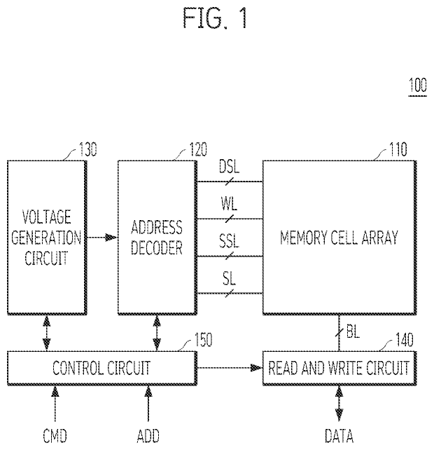

FIG. 1 is a simplified block diagram illustrating a configuration of a semiconductor device according to an embodiment of the present invention disclosure.

Referring to FIG. 1, the semiconductor device 100 may include a memory cell array 110, an address decoder 120, a voltage generation circuit 130, a read and write circuit 140, and a control circuit 150.

The memory cell array 110 may include memory cells. According to an embodiment, the memory cell array 110 may include memory blocks, and each of the memory blocks may include pages. Here, the memory block may be a unit of an erase operation, and the page may be a unit of a read operation. The memory cell array 110 may be connected to the address decoder 120 through a row line such as a source select line SSL, a word line WL, a drain select line DSL, and a local source line SL. The memory cell array 110 may be connected to the read and write circuit 140 through a column line such as a bit line BL.

The control circuit 150 may receive a command CMD and an address ADD from a controller. The control circuit 150 may generate a control signal to perform an internal operation such as a program operation, the read operation, and the erase operation according to the received command CMD. The control circuit 150 may output the control signal to the voltage generation circuit 130, the address decoder 120, and the read and write circuit 140.

The voltage generation circuit 130 may generate an internal voltage having various voltage levels depending upon an internal operation that is to be performed, and may provide the generated internal voltage or voltages to the address decoder 120. For example, the generated internal voltage may be an operation voltage for performing a program operation, a read operation, an erase operation.

According to an embodiment, the internal voltage may be a source voltage to be supplied to the local source line. The source voltage may have a positive level or a negative level.

According to an embodiment, the voltage generation circuit 130 may generate a program voltage, a pass voltage, a source voltage, a bit line voltage, and the like for performing the program operation. The voltage generation circuit 130 may generate a read voltage, a pass voltage, a source voltage, a bit line voltage, and the like for performing a read operation. A read operation may be a verify operation for verifying a program operation or an erase operation. The voltage generation circuit 130 may generate an erase voltage, a Gate-Induced-Drain_Leakage (GIDL) voltage, a source voltage, and the like for performing the erase operation.

The address decoder 120 may activate the source select line, the word line, the drain select line, or the local source line according to an address ADD received from the control circuit 150. A voltage level of the global line may be transferred to the local line.

The read and write circuit 140 may be connected to the memory cell array 110 through the bit lines BL. During the program operation, the read and write circuit 140 may operate as a writer driver and input data Data to be stored in the memory cell array 110. During the read or verify operation, the read and write circuit 140 may operate as a sense amplifier and output the data Data stored in the memory cell array 110.

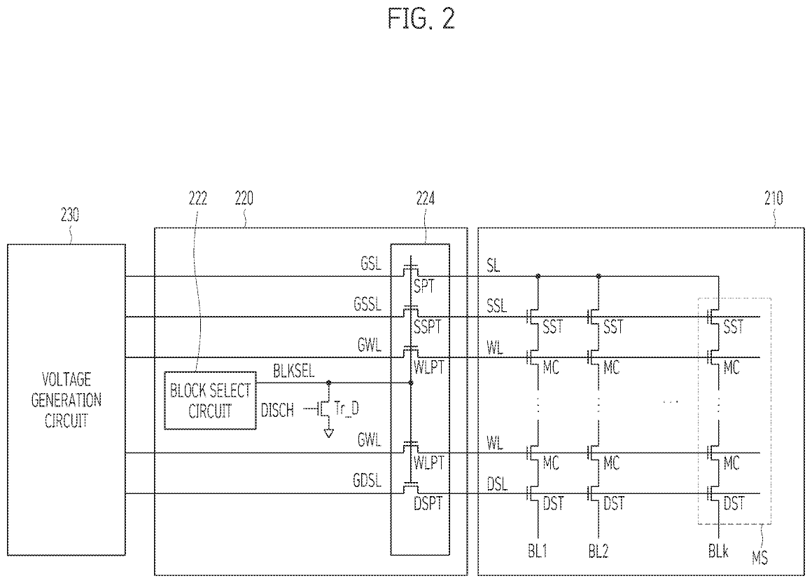

FIG. 2 is a simplified block diagram illustrating a configuration of a semiconductor device according to an embodiment of the present invention disclosure. Hereinafter, a description overlapping a content described above may be omitted.

Referring to FIG. 2, the semiconductor device 200 may include a memory cell array 210, an address decoder 220, and a voltage generation circuit 230.

The memory cell array 210 may include a plurality of memory blocks. Each memory block may include memory strings MS. The memory strings MS in each memory block may be connected between bit lines BL1 to BLk and a local source line SL. Here, k may be an integer of 2 or more. Each memory string MS may include at least one drain select transistor DST, a plurality of memory cells MC, and at least one source select transistor SST.

Gate electrodes of the memory cells MC may be connected to word lines WL. A source select line SSL may be connected to a gate electrode of the source select transistor SST. A connection of the memory string MS and the local source line SL may be controlled by the source select line SSL. When the source select transistor SST is turned on, the memory string MS and the local source line SL may be connected. A drain select line DSL may be connected to a gate electrode of the drain select transistor DST. A connection of the memory string MS and the bit lines BL1 to BLk may be controlled by the drain select line DSL. When the drain select transistor DST is turned on, the memory string MS and the bit line BL may be connected.

The voltage generation circuit 230 may generate operation voltages required for a program operation, a read operation, and an erase operation of memory cells, and may transfer the generated operation voltage to global lines. According to an embodiment, during the program operation, the voltage generation circuit 230 may transfer a program voltage or a pass voltage to a global word line GWL and may transfer a source voltage to a global source line GSL. During the read operation, the voltage generation circuit 230 may transfer a read voltage or a pass voltage to the global word line GWL and may transfer a source voltage to the global source line GSL. During the erase operation, the voltage generation circuit 230 may transfer an erase voltage to at least one of a global drain select line GDSL and a global source select line GSSL, may transfer a ground voltage to the global word line GWL, and may transfer a source voltage to the global source line GSL.

The address decoder 220 may include a block select circuit 222 and a pass circuit 224. The pass circuit 224 may include pass transistors for controlling a connection between a global line and a local line. The pass circuit PSC may include at least one source pass transistor SPT, at least one source select pass transistor SSPT, a plurality of word line pass transistors WLPT, and at least one drain select pass transistor DSPT. The source pass transistor SPT may control a connection between the global source line GSL and the local source line SL. The source select pass transistor SSPT may control a connection between the global source select line GSSL and the source select line SSL. The word line pass transistor WLPT may control a connection between the global word line GWL and the word line WL. The drain select pass transistor DSPT may control a connection between the global drain select line GDSL and drain select line DSL.

The block select circuit 222 may generate a block select signal BLKSEL in response to an address and transfer the generated block select signal BLKSEL to the pass circuit 224. A discharge transistor Tr_D may discharge a line through which the block select signal BLKSEL is transferred in response to a discharge signal DISCH.

The pass circuit 224 may be controlled by the block select signal BLKSEL. The pass circuit 224 may operate in response to the block select signal BLKSEL of the block select circuit 222. The block select signal BLKSEL may be applied to a gate electrode of the pass transistor, and when the pass transistor is turned on, the global line and the local line may be electrically connected.

When the block select signal BLKSEL is activated, the global source line GSL and the local source line LSL may be connected, and the source voltage may be applied to the local source line SL. When the block select signal BLKSEL is activated, the global source select line GSSL and the source select line SSL may be connected. When the block select signal BLKSEL is activated, the global word line GWL and the word line WL may be connected. When the block select signal BLKSEL is activated, the global drain select line GDSL and the drain select line DSL may be connected.

According to the configuration described above, the global source line GSL and the local source line SL may be connected through the source pass transistor SPT, and the source voltage may be applied to the local source line SL. Here, the local source line SL may be the local source line SL separated in a memory block unit or a local source line separated in a sub-block unit. Therefore, the source voltage may be applied in the memory block unit or the sub-block unit.

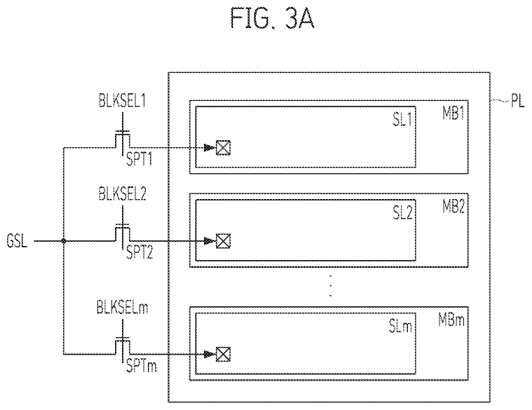

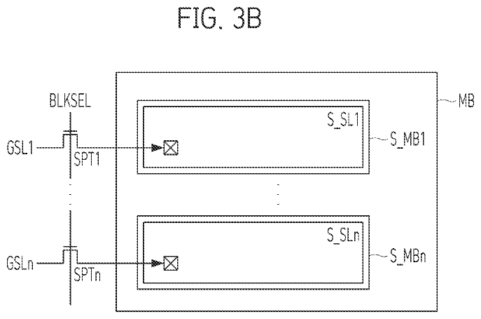

FIGS. 3A and 3B are diagrams illustrating a semiconductor device structure according to an embodiment of the present invention disclosure.

Referring to FIG. 3A, the semiconductor device may include a global source line GSL, local source lines SL1 to SLm, source pass transistors SPT1 to SPTm, and a memory plane PL. Here, m may be an integer of 2 or more. The memory plane PL may include a plurality of memory blocks MB1 to MBm. The local source lines SL1 to SLm may be separated in a memory block unit.

The memory blocks MB1 to MBm may be respectively connected to the local source lines SL1 to SLm. The memory blocks MB1 to MBm may operate using a source voltage supplied through the local source lines SL1 to SLm. The source pass transistors SPT1 to SPTm may control a connection between the global source line GSL and the local source lines SL1 to SLm. The source pass transistors SPT1 to SPTm may operate in response to block select signals BLKSEL1 to BLKSELm. According to an embodiment, when a first block select signal BLKSEL1 is activated, a first source pass transistor SPT1 may be turned on, and the global source line GSL and a first local source line SL1 may be electrically connected. The source voltage of the global source line GSL may be transferred to the first local source line SL1. When a second block select signal BLKSEL2 is activated, the second source pass transistor SPT2 may be turned on, and the source voltage of the global source line GSL may be transferred to a second local source line SL2. When an m-th block select signal BLKSELm is activated, an m-th source pass transistor SPTm may be turned on, and the source voltage of the global source line GSL may be transferred to the m-th local source line SLm.

Referring to FIG. 3B, the semiconductor device may include global source lines GSL1 to GSLn, local source lines S_SL1 to S_SLn, source pass transistors SPT1 to SPTn, and a memory block MB. Here, n may be an integer of 2 or more. The memory block MB may include a plurality of sub-memory blocks S_MB1 to S_MBn. The local source lines S_SL1 to S_SLn may be separated in a sub-memory block unit.

The sub-memory blocks S_MB1 to S_MBn may be respectively connected to the local source lines S_SL1 to S_SLn. The source pass transistors SPT1 to SPTn may control a connection between the global source lines GSL1 to GSLn and the local source lines S_SL1 to S_SLn. The source pass transistors SPT1 to SPTn may operate in response to the block select signal BLKSEL. According to an embodiment, when the block select signal BLKSEL is activated, a first source pass transistor SPT1 may be turned on, and a first global source line GSL1 and a first local source line S_SL1 may be electrically connected. A source voltage of the first global source line GSL1 may be transferred to the first local source line S_SL1. When the block select signal BLKSEL is activated, an n-th source pass transistor SPTn may be turned on, and a source voltage of an n-th global source line GSLn may be transferred to an n-th local source line S_SLn.

According to the configuration described above, the connection of the global source line and the local source line may be controlled through the source pass transistor. Therefore, the same source voltage might not be applied to the entire memory plane. The source voltage may be applied to a selected memory block or a selected sub-memory block, and unselected memory blocks may be floated or grounded.

The local source lines SL1˜SLm may be separated in a memory block unit, or the local source lines S_SL1 to S_SLn may be separated in a sub-memory block unit. Through this, the source voltage may be applied in the memory block unit, or the source voltage may be applied in the sub-memory block unit. Source voltages of different levels may be applied to a selected local source line and an unselected local source lines. Therefore, a source capacitance may be reduced, an operation consumption current may be reduced, and an operation characteristic may be improved.

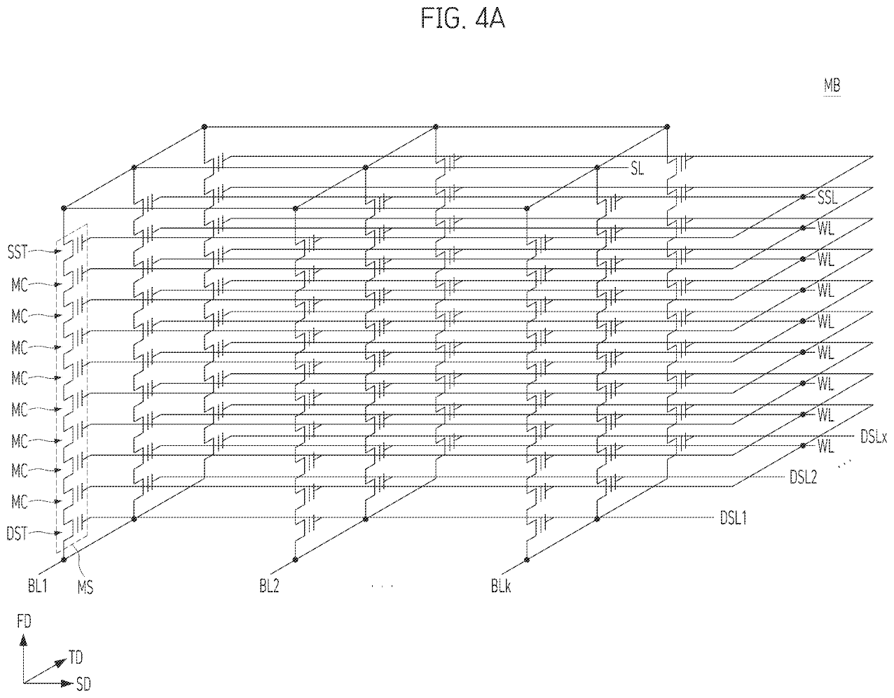

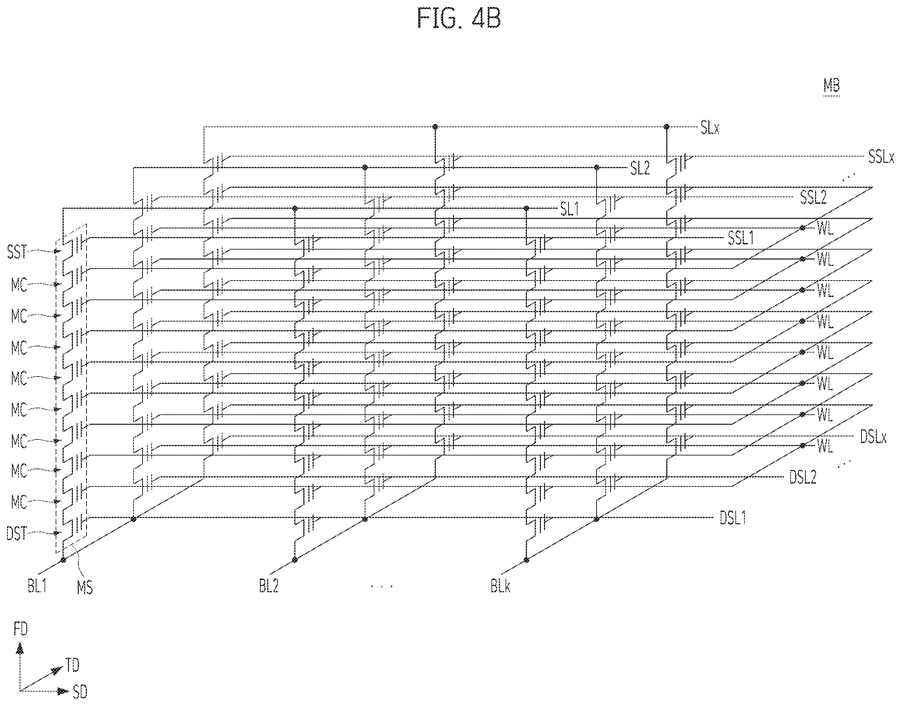

FIGS. 4A and 4B are circuit diagrams of a memory cell array of a semiconductor device according to an embodiment of the present invention disclosure. Hereinafter, a description overlapping a content described above may be omitted.

Referring to FIGS. 4A and 4B, the memory block MB may include a plurality of memory strings MS, and the plurality of memory strings MS may be connected between the bit lines BL1 to BLk and the local source line SL. Each memory string MS may include at least one drain select transistor DST, a plurality of memory cells MC, and at least one source select transistor SST connected in series. In addition, each memory string MS may further include at least one dummy memory cell connected between the drain select transistor DST and the memory cells MC and/or between the source select transistor SST and the memory cells MC.

Gate electrodes of the memory cells MC may be connected to their corresponding word lines WL. Word line voltages (the program voltage, the pass voltage, the read voltage, and the like) required for driving the memory cells may be applied to each of the word lines WL. Gate electrodes of the drain select transistors DST may be connected to their corresponding drain select line DSL. Gate electrodes of the source select transistors SST may be connected to their corresponding source select lines SSL.

Drain select transistors DST arranged in the same row may be connected to same drain select lines DSL1 to DSLx. Drain select transistors DST arranged in different rows may be connected to different drain select lines DSL1 to DSLx. Here, x may be an integer of 2 or more. Memory cells MC of the same level may be connected to the same word line WL.

Referring to FIG. 4A, source select transistors SST of the same level may be connected to the same source select line SSL. Therefore, the local source line SL may be separated in the memory block MB unit, and the erase operation may be performed in the memory block unit.

Referring to FIG. 4B, source select transistors SST arranged in the same row may be connected to the same source select lines SSL1 to SSLx. Source select transistors SST arranged in different rows may be connected to different source select lines SSL1 to SSLx. Therefore, the local source lines SL1 to SLx may be separated in a sub-memory block unit, and the erase operation may be performed in the sub-memory block unit.

According to the configuration described above, memory cells may be stacked in three dimensions. In addition, the erase operation may be performed in the memory block unit or the sub-memory block unit.

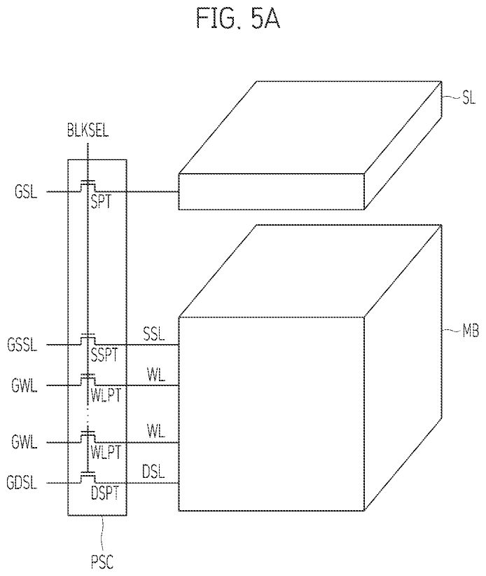

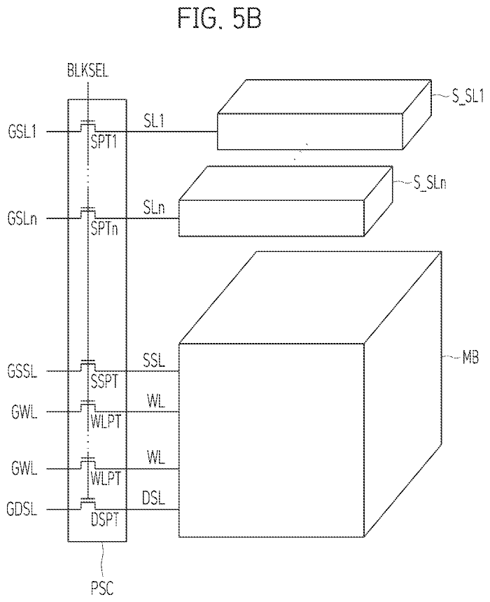

FIGS. 5A and 5B are diagrams illustrating a configuration of a semiconductor device according to an embodiment of the present invention disclosure. Hereinafter, a description overlapping a content described above may be omitted.

Referring to FIGS. 5A and 5B, the semiconductor device may include the memory block MB, the local source line SL, and a pass circuit PSC. The memory block MB may include stacked memory cells.

According to an embodiment, the memory block MB may include a memory string connected between the local source line SL and the bit line BL, and may further include the source select line SSL, the word line WL, and the drain select line DSL. The pass circuit PSC may include a source pass transistor SPT, a source select pass transistor SSPT, a word line pass transistor WLPT, and a drain select pass transistor DSPT.

Referring to FIG. 5A, the local source line SL may be positioned on the memory block MB. The local source line SL may be formed in the memory block unit.

The connection of the global source line GSL and the local source line SL may be controlled by the source pass transistor SPT. The connection of the global source select line GSSL and the source select line SSL may be controlled by the source select pass transistor SSPT. The connection of the global word line GWL and the word line WL may be controlled by the word line pass transistor WLPT. The drain select pass transistor DSPT may control the connection of the global drain select line GDSL and the drain select line DSL.

Referring to FIG. 5B, the local source lines S_SL1 to S_SLn may be positioned on the memory block MB. The local source lines S_SL1 to S_SLn may be formed in the sub-memory block unit. The pass circuit PSC may include source pass transistors SPT1 to SPTn. The local source lines S_SL1 to S_SLn of the same memory block MB may be controlled by the same pass circuit PSC. The first source pass transistor SPT1 may control the connection of the first global source line GSL1 and the first local source line S_SL1. The n-th source pass transistor SPTn may control the connection of the n-th global source line GSLn and the n-th local source line S_SLn. The first to n-th source pass transistors SPT1 to SPTn may be controlled by the same block select signal BLKSEL. When the block select signal BLKSEL is activated, the first to n-th source pass transistors SPT1 to SPTn may be turned on, and the first to n-th global source lines GSL1 to GSLn may be connected to the first to n-th local source lines S_SL1 to S_SLn.

According to the configuration described above, the source voltage may be adjusted in the memory block unit or the sub-memory block unit by separating the local source line in the memory block unit or the sub-memory block unit. Therefore, an operation characteristic of the semiconductor device may be improved.

Table 1 illustrates a bias condition of read, program, and erase operations of a semiconductor device according to an embodiment of the present invention disclosure. For reference, the read operation may be a verify operation.

TABLE 1

| | Read | Program | Erase |
|---|---|---|---|
| BL | V_{BL} | Vcc | Verase |
| selected SL | Vneg | Vcc1 | Verase |
| Unselected SL | OV or V_{BL} | Vcc2 | OV |
| selected WL | Vread | Vpgm | OV |
| unselected WL | VpassR | VpassP | OV |
| selected SSL | Vpass | OV | Vgidl |
| unselected SSL | OV | OV | Vgidl |
| selected DSL | Vpass | Vcc | Vgidl |
| unselected DSL | OV | Vcc→OV | Vgidl |

According to an embodiment, as described with reference to FIG. 5A, the local source line SL may be separated in the memory block unit. In this case, different source voltages may be applied to the selected memory block and the unselected memory block among the plurality of memory blocks belonging to the memory plane.

During the read operation, different voltages may be applied to the selected local source line SL and the unselected local source line SL. A negative source voltage may be applied to the selected local source line SL, and the ground voltage or a bit line voltage VBL may be applied to the unselected local source line SL. The bit line voltage VBL may be applied to the bit line. Here, the bit line voltage VBL may be a precharge voltage. A read voltage Vread may be applied to the selected word line WL, and a pass voltage VpassR may be applied to the unselected word lines WL. Here, the read voltage Vread may have a level at which the memory cell is turned on or turned off according to data stored in the memory cell. The pass voltage VpassR may have a level at which the memory cell is turned on regardless of the data stored in the memory cell. The pass voltage Vpass may be applied to the selected source select line and the selected drain select line, and the ground voltage may be applied to the unselected source select line and the unselected drain select line. Here, the pass voltage Vpass may be a voltage that turns on the source select transistor and the drain select transistor.

Through this, a negative source voltage may be transferred to the selected local source line SL, and the precharge voltage of the bit line may be increased. The unselected local source lines SL may be floated, or the ground voltage or the bit line voltage VBL may be applied to the unselected local source lines SL. Therefore, a cell current may be increased without increasing interference between the bit lines.

During the program operation, a first operation voltage Vcc1 may be applied to the selected local source line SL among the local source lines SL, and a second operation voltage Vcc2 of a level different from that of the first operation voltage Vcc1 may be applied to the unselected local source line SL. A program voltage Vpgm may be applied to the selected word lines WL, and a pass voltage VpassP may be applied to the unselected word lines WL. Here, the pass voltage VpassP may be for boosting a channel of an unselected memory cell, and may have a level lower than that of the program voltage Vpgm. The ground voltage may be applied to the source select lines, and may be grounded after applying the operation voltage Vcc to the drain select lines.

According to an embodiment, by applying the second operation voltage Vcc2 having a higher level than that of the first operation voltage Vcc1 to the unselected local source line SL, an operation voltage of a relatively high level may be applied to the unselected local source line SL, and a boosting level may be increased. By increasing channel boosting of unselected memory strings, an operation window may be increased. According to an embodiment, when the boosting level is increased by GIDL, by applying the second operation voltage Vcc2 having a lower level than that of the first operation voltage Vcc1 to the unselected local source line SL, an operation voltage of a relatively low level may be applied to the unselected local source line SL and the boosting level may be decreased. According to an embodiment, by applying an operation voltage of different levels to the unselected local source lines SL, the channel boosting may be adjusted in the sub-block unit.

According to an embodiment, as described with reference to FIG. 5B, the local source line SL may be separated in the sub-memory block unit. In this case, different source voltages may be applied to the selected sub-memory block and the unselected sub-memory block among the plurality of sub-memory blocks belonging to the memory block.

During the erase operation, an erase voltage Verase may be applied to a selected local source line S_SL1 among the local source lines S_SL1 to S_SLn, and the ground voltage may be applied to unselected local source lines S_SL2 to S_SLn. The ground voltage may be applied to the word lines WL, and a GIDL voltage Vgidl may be applied to the source select lines SSL and the drain select lines DSL. Through this, the erase operation may be performed only on sub-memory blocks connected to the selected local source line S_SL1. Therefore, the erase operation may be performed in the sub-memory block unit.

During the program operation, the first operation voltage Vcc1 may be applied to the selected local source line S_SL1 among the local source lines S_SL1 to S_SLn, and the second operation voltage Vcc2 having a higher level than that of the first operation voltage Vcc1 may be applied to the unselected local source lines S_SL2 to S_SLn. Through this, the channel boosting of the unselected memory strings may be increased and the operation window may be increased. In addition, by applying operation voltages of different levels to the unselected local source lines SL, channel boosting may be adjusted in the sub-block unit.

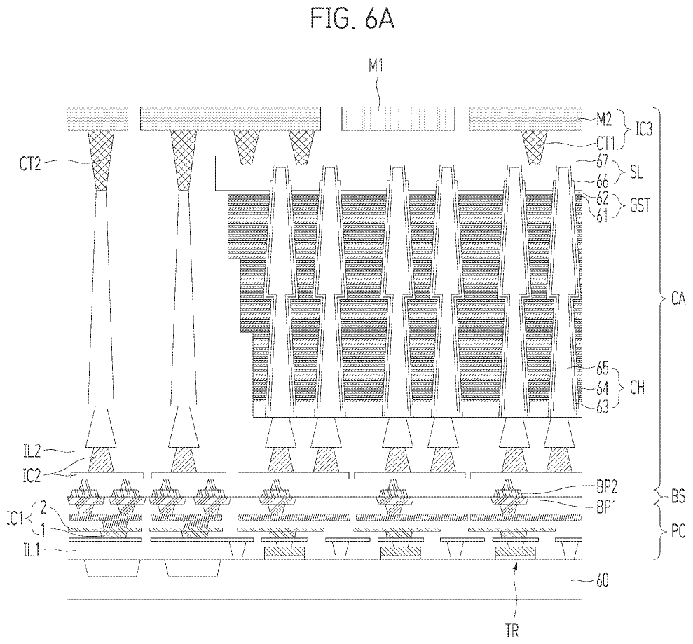

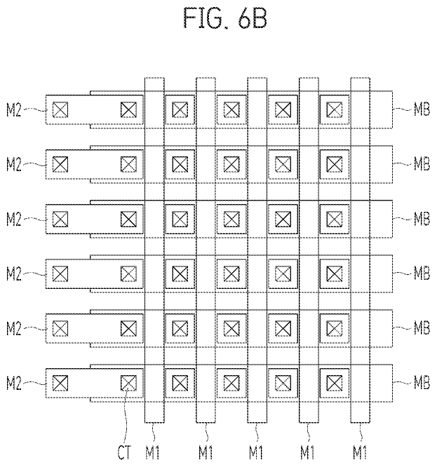

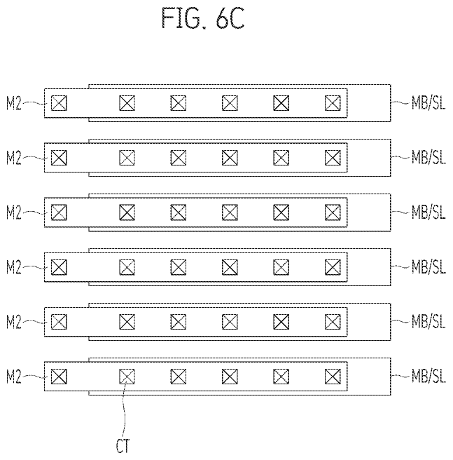

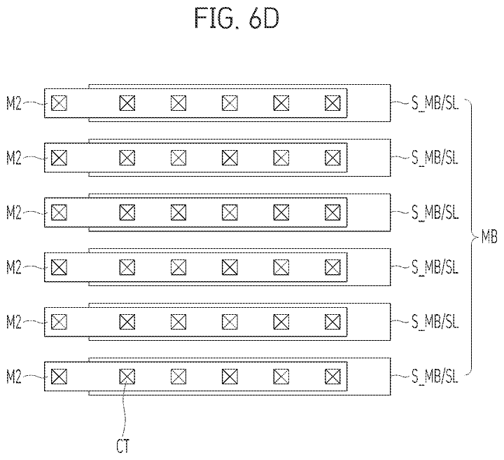

FIGS. 6A to 6D are diagrams illustrating a semiconductor device structure according to an embodiment of the present invention disclosure. Hereinafter, a content overlapping the content described above may be omitted.

Referring to FIG. 6A, the semiconductor device may include a substrate 60, a peripheral circuit PC formed over the substrate 60, a memory cell array CA disposed over the peripheral circuit PC, and a bonding structure BS disposed between the peripheral circuit PC and the memory cell array CA. The peripheral circuit PC may be positioned on the substrate 60 and may include a circuit such as a page buffer, a row-decoder, and a sense amplifier. For example, the peripheral circuit PC may include transistors TR and corresponding first interconnection structures IC1.

The memory cell array CA may include a gate structure GST, a local source line SL, a plurality of channel structures CH passing through the gate structure GST, second interconnection structures IC2, and third interconnection structures IC3. The gate structure GST may include gate lines 61 and insulating layers 62 alternately stacked. The gate lines 61 may be word lines, a source select line, a drain select line, and the like. The channel structures CH may be spaced apart from each other and may extend through the gate structure GST. Each of the channel structures CH may include a channel layer 63, a memory layer 64 surrounding the channel layer 63, and an insulating core 65 in the channel layer 63.

The local source line SL may be positioned on the gate structure GST. The local source line SL may be formed in the memory block unit or the sub-memory block unit. The local source line SL may include a conductive layer and may be a single layer or multiple layers. According to the illustrated embodiment of FIG. 6A, the local source line SL may include a first conductive layer 66 and a second conductive layer 67 formed on the first conductive layer 66. The first and second conductive layers 66 and 67 may have different resistivities. For example, the first conductive layer 66 may include polysilicon, while the second conductive layer 67 may include a metal. The channel structure CH may extend into the local source line SL through the gate structure GST. The channel layer 63 and the local source line SL may be connected (i.e., electrically connected) to each other. The channel layer 63 and the local source line SL may be connected directly or may be connected through an epitaxial pattern.

The peripheral circuit PC and the memory cell array CA may be electrically connected through the bonding structure BS. The bonding structure BS may include a first bonding pad BP1 and a second bonding pad BP2. The first bonding pad BP1 and the second bonding pad BP2 may each include a metal such as, for example, copper. The first bonding pad BP1 and the second bonding pad BP2 may be in direct contact to each other. The first and second bonding pads BP1 and BP2 may have the same or different cross sectional area. For example, in the illustrated embodiment of FIG. 6A the first bonding pad BP1 may have a larger cross-sectional area than the cross-sectional area of the second bonding pad BP2.

The first interconnection structures IC1 may be positioned in a first interlayer insulating layer IL1. Through the first interconnection structures IC1, the first bonding pads BP1 and the peripheral circuit PC may be electrically connected. Each of the first interconnection structures IC1 may include a contact plug 1, a line 2, and the like. The second interconnection structures IC2 and the third interconnection structures IC3 may be positioned in a second interlayer insulating layer IL2. The second interconnection structures IC2 may be positioned under the gate structure GST and may be electrically connected to the memory cell array CA. The third interconnection structures IC3 may be positioned on the gate structure GST and may be electrically connected to the memory cell array CA. The second bonding pads BP2 and the memory cell array CA may be electrically connected through the second interconnection structures IC2 and the third interconnection structures IC3.

The third interconnection structure IC3 may include a first line M1, a second line M2, a first contact plug CT1, and a second contact plug CT2. The first line M1 may be a line for transferring an internal operation voltage, and the second line M2 may be a line for transferring the source voltage.

A shape and an arrangement of the second line M2 may vary according to the local source line SL. Referring to FIG. 6B, the first lines M1 may extend in a direction crossing the memory blocks MB, and the second lines M2 may be positioned between the first lines M1. The second line M2 and the local source line SL may be connected through the contact plug CT. Referring to FIG. 6C, the local source line SL may be formed in the memory block unit, and the second line M2 may also be formed in the memory block unit. Referring to FIG. 6D, the local source line SL may be formed in the sub-memory block unit, and the second line M2 may also be formed in the sub-memory block unit.

According to the structure described above, the peripheral circuit PC and the memory cell array CA may be manufactured as separate wafers, and may then be electrically connected through the bonding structure BS. Moreover, because the local source line SL is positioned on the gate structure GST, the local source line SL may be separated in the memory block unit or the sub-memory block unit.

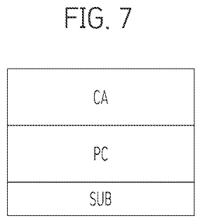

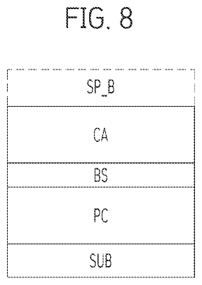

A structure and a manufacturing method according to the above-described embodiments may be applied to semiconductor devices of various structures. FIGS. 7 and 8 illustrate a schematic configuration of a semiconductor device to which the above-described embodiments are applicable.

FIG. 7 is a configuration diagram of a semiconductor device according to an embodiment of the present invention disclosure.

Referring to FIG. 7, the semiconductor device may include the substrate SUB, the peripheral circuit PC disposed over the substrate SUB, and the memory cell array CA disposed over the peripheral circuit PC. Hence, according to this embodiment, the peripheral circuit PC and the memory cell array CA may be formed on the same substrate.

The substrate SUB may include a semiconductor material. For example, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductors may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. According to an embodiment, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method and may partially include metal. The substrate SUB may have a single crystalline, polycrystalline, or amorphous state. The substrate SUB may include an impurity of group II, group III, group IV, group V, or group VI. According to an embodiment, the substrate SUB may include an n-well region doped with an n-type impurity and/or a p-well region doped with a p-type impurity.

The peripheral circuit PC may be positioned between the substrate SUB and the memory cell array CA. The peripheral circuit PC may include a row decoder, a column decoder, a page buffer, a logic circuit, a control circuit, a sense amplifier, an input/output circuit, and the like. According to an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage and may include a contact plug, a line, and the like.

The memory cell array CA may include memory cells. According to an embodiment, the memory cell array CA may include memory strings connected between a source line and a bit line, and each memory string may include stacked memory cells. According to an embodiment, the memory cell array CA may include memory cells connected between a word line and the bit line. The memory cell array CA may further include an interconnection structure.

FIG. 8 is a configuration diagram of a semiconductor device according to an embodiment of the present invention disclosure.

Referring to FIG. 8, the semiconductor device may include the substrate SUB, the peripheral circuit PC disposed over the substrate SUB, the bonding structure BS disposed between the peripheral circuit PC and the memory cell array CA, and the memory cell array CA disposed over the bonding structure BS. Here, the peripheral circuit PC and the memory cell array CA may be formed on separate substrates and then bonded together. The semiconductor device may further include a support base SP_B disposed over the cell array CA.

The substrate SUB may be used as a support in a process of forming the peripheral circuit PC while the support base SP_B may be used as a support in a process of forming the memory cell array CA. According to an embodiment, after manufacturing each of the first wafer including the memory cell array CA and the second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, an SOI substrate, a GeOI substrate, or the like. The support base SP_B may be a bulk wafer, an epitaxial layer grown in an SEG method, or a layer formed in an MILC method. The support base SP_B may have a single crystalline, polycrystalline, or amorphous state. The support base SP_B may include an impurity of group II, group III, group IV, group V, or group VI.

The bonding structure BS may be for connecting the cell array CA and the peripheral circuit PC. According to an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, or the like. The bonding pad may include a metal and/or an alloy of copper, aluminum, and the like. The bonding interface may include a non-metal-non-metal interface, a metal-metal interface, or the like. The cell array CA and the peripheral circuit PC may be electrically connected by the bonding structure BS.

For reference, the interconnection structure included in the cell array CA and/or peripheral circuit PC may be directly connected without a bonding pad. According to an embodiment, a bonding layer included in the cell array CA and a bonding layer included in the peripheral circuit PC may be bonded to form a bonding interface, and an interconnection structure included in the cell array CA and an interconnection structure included in the peripheral circuit PC may be directly connected. Through this, contact plugs, lines, and the like formed on different wafers may be electrically connected without a separate bonding pad.

Other configurations may be identical or similar to those described above with reference to FIG. 7.

Meanwhile, the semiconductor device may have a structure in which the embodiments described above with reference to FIGS. 7 and 8 are combined or may have a structure in which a portion of the embodiments described above with reference to FIGS. 7 and 8 is modified. In the embodiment described with reference to FIGS. 7 and 8, positions of the memory cell array CA and the peripheral circuit PC may be changed. At least one memory cell array CA and/or at least one peripheral circuit PC may be additionally bonded to the embodiment described with reference to FIG. 7. According to an embodiment, a portion of the peripheral circuitry PC may be positioned in the memory cell array CA.

Although embodiments according to the technical concept of the present invention disclosure have been described with reference to the accompanying drawings, this is only for describing an embodiment according to the concept of the present invention disclosure, and the present invention disclosure is not limited to the above-described embodiments. Within the scope of the technical concept of the present invention disclosure, various forms of substitution, modification, change, and combination of the embodiments will be possible by those skilled in the art to which the present invention disclosure belongs, and these also belong to the scope of the present invention disclosure.

What is claimed is:

1. A semiconductor device comprising:
a first source pass transistor controlling a connection between a global source line and a first local source line;
a second source pass transistor controlling a connection between the global source line and a second local source line;
a first memory block using a first source voltage supplied through the first local source line; and
a second memory block using a second source voltage supplied through the second local source line.

2. The semiconductor device of claim 1, further comprising:
a voltage generation circuit generating the first and second source voltages and supplying the first and second source voltages to the global source line.

3. The semiconductor device of claim 1, wherein the first memory block includes a drain select line, and
the semiconductor device further comprises:
a global drain select line; and
a drain select pass transistor controlling a connection between the global drain select line and the drain select line.

4. The semiconductor device of claim 1, wherein the first memory block includes word lines, and
the semiconductor device further comprises:
global word lines; and
word line pass transistors controlling a connection between the global word lines and the word lines.

5. The semiconductor device of claim 1, wherein the first memory block includes a source select line, and
the semiconductor device further comprises:
a global source select line; and
a source select pass transistor controlling a connection between the global source select line and the source select line.

6. The semiconductor device of claim 1, wherein during a read operation, the first memory block is selected, and a negative voltage is applied to the first local source line as the first source voltage.

7. The semiconductor device of claim 6, wherein a ground voltage is applied to the second local source line as the second source voltage.

8. The semiconductor device of claim 1, wherein during a program operation, the first memory block is selected, and a first operation voltage is applied to the first local source line as the first source voltage.

9. The semiconductor device of claim 8, wherein a second operation voltage of a level different from that of the first operation voltage is applied to the second local source line as the second source voltage.

10. A semiconductor device comprising:
a first source pass transistor controlling a connection between a first global source line and a first local source line;
a second source pass transistor controlling a connection between a second global source line and a second local source line; and
a memory block including a first sub-memory block using a first source voltage supplied through the first local source line and a second sub-memory block using a second source voltage supplied through the second local source line.

11. The semiconductor device of claim 10, further comprising:
a voltage generation circuit generating the first source voltage and the second source voltage and supplying the first source voltage and the second source voltage to the first global source line and the second global source line.

12. The semiconductor device of claim 10, wherein during a program operation, the first sub-memory block of the memory block is selected, and a first operation voltage is applied to the first local source line as the first source voltage.

13. The semiconductor device of claim 12, wherein a second operation voltage of a level different from that of the first operation voltage is applied to the second local source line as the second source voltage.

14. The semiconductor device of claim 10, wherein during an erase operation, the first sub-memory block of the memory block is selected, and an erase voltage is applied to the first local source line as the first source voltage.

15. The semiconductor device of claim 14, wherein a ground voltage is applied to the second local source line as the second source voltage.

16. A semiconductor device comprising:
a peripheral circuit;
a gate structure including stacked gate lines;
a bonding structure positioned between the peripheral circuit and the gate structure and electrically connecting the peripheral circuit and the gate structure;
local source lines positioned on the gate structure; and
source pass transistors controlling a connection between the local source lines and at least one global source line.

17. The semiconductor device of claim 16, wherein the local source lines include a first local source line and a second local source line,
the at least one global source line includes a first global source line and a second global source line, and
the source pass transistors include a first source pass transistor controlling a connection between the first global source line and the first local source line, and a second source pass transistor controlling a connection between the second global source line and the second local source line.

18. The semiconductor device of claim 16, wherein the local source line includes a first local source line and a second local source line, and
the source pass transistor includes a first source pass transistor controlling a connection between the global source line and the first local source line, and a second source pass transistor controlling a connection between the global source line and the second local source line.
